(19) United States
(12) Patent Application Publication
(10) Pub. No.: US 2010/0315149 A1
(43) Pub. Date: Dec. 16, 2010

(54) High-speed data compared latch with auto-adjustment of offset

(75) Inventors: Guosheng Wu, Chengdu (CN); Bin Li, Chengdu (CN)

Correspondence Address: ZHEN ZHENG LU, 1730 HUNTINGTON DRIVE #304, DUARTE, CA, 91010, US

(73) Assignee: IPGoal Microelectronics (SiChuan) Co., Ltd.

(21) Appl. No.: 12/797,608

(22) Filed: Jun. 10, 2010

(30) Foreign Application Priority Data
Jun. 11, 2009 (CN) 200910059569.4

(51) Int. Cl. H03L 5/00

(52) U.S. Cl. 327/307

(57) ABSTRACT

A high-speed data compared latch with auto-adjustment of offset, includes input pair transistors P, input pair transistors N, a compared latch module, an input control module, an output control module and a offset logic control module, the offset logic control module creates two control signals that regulate the number of input pair transistors P and input pair transistors N respectively according to reset signal RESET and the latched output of the compared latch module, and achieve self correcting of offset through regulating the number of the input pair transistors P and the input pair transistors N. The present invention is a feedback mechanism, automatically trimming the number of differential input pair to achieve the trimming differential pair operating point and the threshold voltage, eliminate the process variation, and latch on more precise control match the differential input pair transistors of the high-speed data compared latch in receiver accurately.

### FIELD OF INVENTION

The present invention relates to a high-speed data compared latch, and more particularly to a high-speed data compared latch with auto-adjustment of offset

### DESCRIPTION OF RELATED ARTS

High-speed ADC is the important component part of high speed data communication and signal processing circuit of modern times, and the design of the high-speed data compared latch is the key link of the design of High-speed ADC. In each ADC (analog-digital converter) with high speed and resolution, the high-speed data compared latch largely determines the highest resolution and the Maximum conversion speed of the ADC. However, in the high-speed data compared latch, the mismatch of differential input pair transistors determines the compared accuracy of the high-speed data compared latch to some extent, and decreases the latching timing margin of the high-speed data compared latch, so it influences the accuracy and speed of ADC.

Offset is an important factor one should concern in the design of high performance CMOS circuit. And the circuit offset can be divided into: the manufacturing process and packaging process, after the uncertainty caused by mechanical pressure. The amount of offset voltage is mainly determined by the input-output differential pair, and differential input signal is likely to contain offset voltage itself; the offset voltage determines the performance and manufacturing yield of the product to some extent.

When not using self-correction, generally, the offset voltage caused by mismatch is between positive/negative 5 mV if a good COMS analog circuit layout follows the rules of layout design. The offset voltage can be decreased by enlarging the size of input and output stages differential pair, however, the input and output capacitors will become too high in this way, and it narrows the accuracy and speed of the circuit; such that many high accuracy systems need electronics technology to eliminate mismatch; generally, the technology of auto-zero requires passive device such as capacitors to get mismatch compensation.

### SUMMARY OF THE PRESENT INVENTION

A main object of the present invention is to provide a high-speed data compared latch with auto-adjustment of offset, which is capable of performing self correcting of offset in the high-speed data compared latch under the premise of not using passive devices (such as capacitors) or enlarging the size of input and output stages differential pair, it is also characteristic of easy accuracy controlling and low power consumption.

The technical solution of the Present Invention is as follows:

A high-speed data compared latch with auto-adjustment of offset, which is characterized by: comprising input pair transistors P, input pair transistors N, a compared latch module, an input control module, an output control module and an offset logic control module, wherein the input control module creates two signals to control the input pair transistors P and the input pair transistors N respectively; then the input pair transistors P and the input pair transistors N output connections to the compared latch module respectively; the latched output of the compared latch module simultaneously connects to the output control module and the offset logic control module; the offset logic control module creates two control signals that regulate the number of the input pair transistors P and the input pair transistors N respectively according to reset signal RESET and the latched output signal of the compared latch module, and achieve self correcting of offset through regulating the number of the input pair transistors P and the input pair transistors N; the output of the output control module is the output of the high-speed data compared latch with auto-adjustment of offset

The input pair transistors P are composed of N+1 input MOS transistors and N+1 switching transistors that are respectively connected in series and then connected in parallel; the input pair transistors N are composed of M+1 input MOS transistors and M+1 switching transistors that are respectively connected in series and then connected in parallel; wherein N and M are greater than or equal to zero, and N and M may be equivalent or not.

The compared latch module is capable of comparing the signals that are output by the input pair transistors P and the input pair transistors N for getting corresponding latched output under the control of an input clock.

The offset logic control module creates the signal IN_EN as enable control signal of the input control module through the co-acting of reset signal RESET and the latched output signal of the compared latch module.

The offset logic control module creates the signal OUT_EN as enable control signal of the output control module through the co-acting of reset signal RESET and the latched output signal of the compared latch module.

The offset logic control module creates two signals CON_P[0:N],CON_N[0:M] as the control signals of the switching transistor that in parallel with the input pair transistors P/ input pair transistors N, that is the control signals of choosing the number of the input pair transistors P/ input pair transistors N.

The work process of the high-speed data compared latch is as follows:

When RESET is in effect (RESET=1), the offset logic control module is in reset:

IN_EN=0: the input control module creates two signals INN_P,INN_N under the control of the signal IN_EN, the two signals INN_P,INN_N are both the common mode of the input data of the high-speed data compared latch with auto-adjustment of offset;

OUT_EN=0: the output control module is in reset, the output of the high-speed data compared latch is always zero;

CON_P[0:N]/CON_N[0:M] are the control signals of N+1/M+1, they control the number of the two input pair transistors, in this state, CON_P[0:N]=I1/CON_N[0:M]=I2 are the default, wherein I1/I2 meet: 0<I<N+1 and 0<I<M+1;

When RESET is not in effect (RESET=0), the output of the offset logic control module are IN_EN=0/OUT_EN=0, the input of the input pair transistors P and the input pair transistors N is INN_P=INN_N, the high-speed data compared latch with auto-adjustment of offset is in the state of auto-adjustment, the output remains zero. the compared latch module compares the output of the input pair transistors P and the input pair transistors N when the rise time of the input clock comes, the result of comparison is unchanging under the input clock's high status and not influenced by the input state of the input pair transistors P and the input pair transistors N, that is the compared latch module compares data only on the rise-time of the input clock; when the input clock turns in low status, the result of comparison is sent to-offset logic control module and output control module simultaneously as the latched output of the compared latch module. The offset logic control module accumulates the compared latch output data in x input clock cycles, carries out the auto-adjustment of offset through the judgement of the accumulated value, the concrete process is as follows:

if the accumulated value of the compared latch output data is zero in x input clock cycles, it means the number of the input pair transistors N is bigger than the input pair transistors P by mismatch, the output control signals CON_P[0:N] of the offset logic control module keep unchanging, CON_N[0:M] reduce one on the original basis, that is the number of the input pair transistors N reduce one on the original basis on the state that the number of the input pair transistors P keep unchanging; and at the same time the accumulated counting value of the offset logic control module resets to zero;

if the accumulated value of the compared latch output data is X in x input clock cycles, it means the number of the input pair transistors P is bigger than the input pair transistors N by mismatch, the output control signals CON_N[0:M] of the offset logic control module keep unchanging, CON_P[0:N] reduce one on the original basis, that is the number of the input pair transistors P reduce one on the original basis on the state that the number of the input pair transistors N keep unchanging; and at the same time the accumulated counting value of the offset logic control module resets to zero;

the above process is repeated the accumulated value of the compared latch output data is bigger than zero and smaller than X in x input clock cycles, which indicates that auto-correcting to the mismatch of the input pair transistors P and the input pair transistors N is finished.

after finishing the auto-correcting to the mismatch, the output of the-offset logic control module IN_EN=1,the input control module enters into the normal operation mode, INN_P is the positive input of the input data of the high-speed data compared latch with auto-adjustment of offset, INN_N is the negative input of the input data of the high-speed data compared latch with auto-adjustment of offset; the output of the offset logic control module OUT_EN=1,the output control module enters into the normal operation mode, the output is the normal result of comparison.

The functional effect of the present invention is as follows:

The present invention is a feedback mechanism, automatically trimming the number of differential input pair to achieve the trimming differential pair operating point and the threshold voltage, eliminate the process variation, and match the differential input pair transistors of the high-speed data compared latch in receiver accurately, so then reducing the sampling error produced by the threshold deviation of the pair transistors and improving the compared accuracy of high data compared latch.

These and other objectives, features, and advantages of the present invention will become apparent from the following detailed description, the accompanying drawings, and the appended claims.

### BRIEF DESCRIPTION OF THE DRAWINGS

FIG. 1 is schematic view of according to a preferred embodiment of the present invention.

FIG. 2 is schematic view of according to the second preferred embodiment of the present invention.

FIG. 3 is the working flow chart of the present invention.

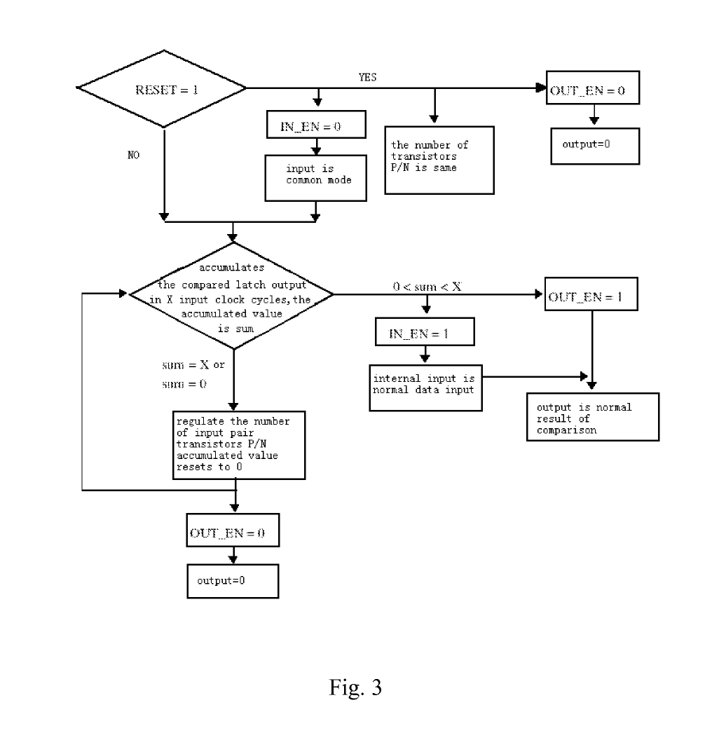

### DETAILED DESCRIPTION OF THE PREFERRED EMBODIMENT

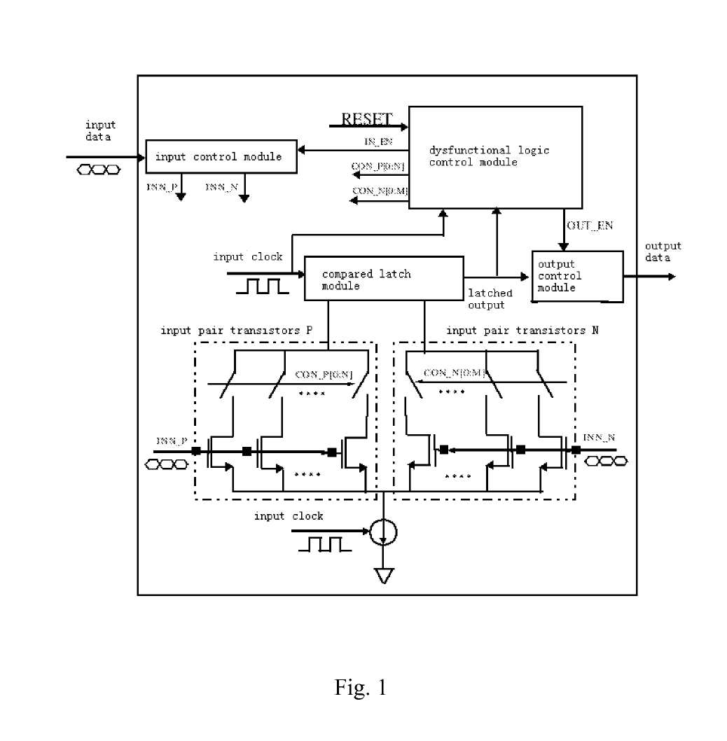

Referring to FIG. 1 of the drawings, according to a preferred embodiment of the present invention is illustrated:

A high-speed data compared latch with auto-adjustment of offset, which is characterized by: comprising input pair transistors P, input pair transistors N, a compared latch module, an input control module, an output control module and an offset logic control module, wherein the input control module creates two signals to control the input pair transistors P and the input pair transistors N respectively; then the output of the input pair transistors P and the output of the input pair transistors N connect to the compared latch module respectively; the latched output of the compared latch module simultaneously connects to the output control module and the offset logic control module; the offset logic control module creates two control signals that regulate the number of input pair transistors P and input pair transistors N respectively according to reset signal RESET and the latched output of the compared latch module, and achieve self correcting of offset through regulating the number of input pair transistors P and input pair transistors N; the output of the output control module is the output of the high-speed data compared latch with auto-adjustment of offset

The input pair transistors P are composed of N+1 input MOS transistors and N+1 switching transistors that are respectively connected in series and then connected in parallel, N≧1.

The compared latch module is capable of comparing the signals that outputted by the input pair transistors P and the input pair transistors N for getting corresponding latched output under the control of an input clock.

The offset logic control module creates IN_EN signal as enable control signal of the input control module through the co-acting of reset signal RESET and the latched output signal of the compared latch module.

The offset logic control module creates OUT_EN signal as enable control signal of the output control module through the co-acting of reset signal RESET and the latched output signal of the compared latch module.

The offset logic control module creates two signals CON_P[0:N], CON_N[0:M] as the control signals that regulate the number of the input pair transistors P and the input pair transistors N respectively

The work process of the high-speed data compared latch is as follows:

When RESET is in effect (RESET=1), the offset logic control module is in reset:

IN_EN=0: the input control module creates two signals INN_P,INN_N under the control of the signal IN_EN, the two signals INN_P,INN_N are both the common mode of the input data of the high-speed data compared latch with auto-adjustment of offset;

OUT_EN=0: the output control module is in reset, the output of the high-speed data compared latch is always zero;

CON_P[0:N]/CON_N[0:N] are N+1 respectively bit control signals, they control the number of the two input pair transistors respectively, in this state, CCON_P[0:N]=CON_N[0:N]=I is the default, wherein I meets: 0<I<N+1;

When RESET is not in effect (RESET=0), the output of the offset logic control module are IN_EN=0/OUT_EN=0, the input of the input pair transistors P and the input pair transistors N is INN_P=INN_N, the high-speed data compared latch with auto-adjustment of offset is in the state of auto-adjustment, the output remains zero. the compared latch module compares the output of the input pair transistors P and the input pair transistors N when the rise time of the input clock comes, the result of comparison is unchanging under the input clock's high status and not influenced by the input state of the input pair transistors P and the input pair transistors N, when the input clock turns to low status, the result of comparison is sent to the offset logic control module and the output control module simultaneously as the latched output of the compared latch module. The offset logic control module accumulates the compared latch output data in x input clock cycles, carries out the auto-adjustment of offset through the judgement of the accumulated value.

The process is as follows:

if the accumulated value of the compared latch output data is zero in x input clock cycles, it means the number of the input pair transistors N is bigger than the input pair transistors P by mismatch, the output control signals CON_P[0:N] of the offset logic control module keep unchanging, CON_N[0:N] reduce one on the original basis, that is the number of the input pair transistors N reduce one on the original basis on the state that the number of the input pair transistors P keep unchanging; and at the same time the accumulated counting value of the offset logic control module resets to zero;

if the accumulated value of the compared latch output data is X in x input clock cycles, it means the number of the input pair transistors P is bigger than the input pair transistors N by mismatch, the output control signals CON_N[0:N] of the offset logic control module keep unchanging, CON_P[0:N] reduce one on the original basis, that is the number of the input pair transistors P reduce one on the original basis on the state that the number of the input pair transistors N keep unchanging; and at the same time the accumulated counting value of the offset logic control module resets to zero;

the above process is repeated until the accumulated value of the compared latch output data is bigger than zero and smaller than X in x input clock cycles, which indicates that the auto-correcting to the mismatch of the input pair transistors P and the input pair transistors N is finished;

after finishing the auto-correcting to the mismatch, the output of the offset logic control module IN_EN=1,the input control module enters into the normal operation mode, INN_P is the positive input of the input data of the high-speed data compared latch with auto-adjustment of offset, INN_N is the negative input of the input data of the high-speed data compared latch with auto-adjustment of offset; the output of the offset logic control module OUT_EN=1,the output control module enters into the normal operation mode, the output is the normal result of comparison.

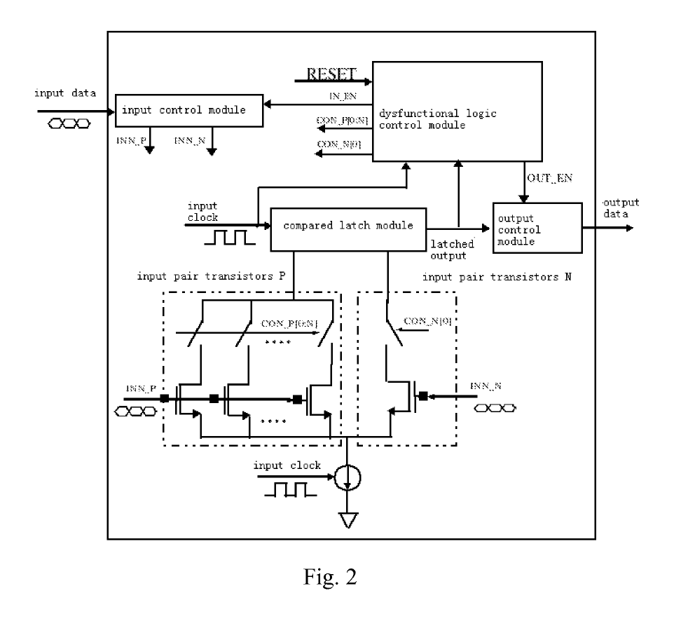

Referring to FIG. 2 of the drawings, according to a preferred embodiment of the present invention is illustrated:

A high-speed data compared latch with auto-adjustment of offset, which is characterized by: comprising input pair transistors P, input pair transistors N, a compared latch module, an input control module, an output control module and an offset logic control module, the input control module creates two signals to control the input pair transistors P and the input pair transistors N respectively; then the output of the input pair transistors P and the output of the input pair transistors N connect to the compared latch module respectively; the latched output of the compared latch module simultaneously connects to the output control module and the offset logic control module; the offset logic control module creates two control signals that regulate the number of input pair transistors P and input pair transistors N respectively according to reset signal RESET and the latched output of the compared latch module, and achieve self correcting of offset through regulating the number of input pair transistors P and input pair transistors N; the output of output control module is a high-speed data compared latch with auto-adjustment of offset.

The input pair transistors P are composed of N+1 input MOS transistors and N+1 switching transistors that are connected in series and then connected in parallel; wherein N≧1, The input pair transistors N are composed of a group of input MOS transistors and a switching transistor that are connected in series and then connected in parallel.

The compared latch module is capable of comparing the signals that are output by the input pair transistors P and the input pair transistors N for getting corresponding latched output under the control of an input clock.

The offset logic control module creates IN_EN signal as enable control signal of the input control module through the co-acting of reset signal RESET and the latched output signal of the compared latch module.

The offset logic control module creates OUT_EN signal as enable control signal of the output control module through the co-acting of reset signal RESET and the latched output signal of the compared latch module.

The offset logic control module creates two signals CON_P[0:N],CON_N[0], wherein CON_P[0:N] is the control signal of the number of the input transistors, CON_N[0] is the control signal of the switching transistor g of the input pair transistors N, and CON_N[0]=1 is always in effect.

The work process of the high-speed data compared latch is as follows:

when RESET is in effect (RESET=1), the offset logic control module is in reset:

IN_EN=0: the input control module creates two signals INN_P,INN_N under the control of the signal IN_EN, the two signals INN_P,INN_N are both the common mode of the input data of the high-speed data compared latch with auto-adjustment of offset

OUT_EN=0: the output control module is in reset, the output of the high-speed data compared latch is always zero;

CON_P[0:N] is the control signal of N+1, it controls the number of the input pair transistors P, in this state, CON_P[0:N]=I is the default, wherein I meets: 0<I<N+1, CON_N[0] is the control signal of the switching transistors of the input pair transistors N, and CON_N[0]=1 is always in effect;

when RESET is not in effect (RESET=0), the output of the offset logic control module is IN_EN=0/OUT_EN=0, the input of the input pair transistors P and the input pair transistors N is INN_P=INN_N, the high-speed data compared latch with auto-adjustment of offset is in the state of auto-adjustment, the output remains zero. the compared latch module compares the output of the input pair transistors P and the input pair transistors N when the rise time of the input clock comes, the result of comparison is unchanging under the input clock's high status and not influenced by the input state of the input pair transistors P and the input pair transistors N, when the input clock turns in low status, the result of comparison is sent to offset logic control module and output control module simultaneously as the latched output of the compared latch module. The offset logic control module accumulates the compared latch output data in x input clock cycles, carries out the auto-adjustment of offset through the judgement of the accumulated value.

The concrete process is as follows:

if the accumulated value of the compared latch output data is zero in x input clock cycles, it means the number of the input pair transistors N is bigger than the input pair transistors P by mismatch, the control signals CON_P[0:N] output by the offset logic control module adds one on the original basis, that is the number of the input pair transistors P adds one on the original basis, and at the same time the accumulated counting value of the-offset logic control module resets to zero;

if the accumulated value of the compared latch output data is X in x input clock cycles, it means the number of the input pair transistors P is bigger than the input pair transistors N by mismatch, the control signals CON_P[0:N] output by the output control module reduces one on the original basis, that is the number of the input pair transistors P reduce one on the original basis, and at the same time the accumulated counting value of the offset logic control module resets to zero;

the above process is repeated until the accumulated value of the compared latch output data is bigger than zero and smaller than X in x input clock cycles, which indicates that auto-correcting to the mismatch of the input pair transistors P and the input pair transistors N is finished;

after finishing the auto-correcting to the mismatch, the output of the offset logic control module IN_EN=1,the input control module enters into the normal operation mode, INN_P is the positive input of the input data of the high-speed data compared latch with auto-adjustment of offset, INN_N is the negative input of the input data of the high-speed data compared latch with auto-adjustment of offset; the output of the offset logic control module OUT_EN=1,the output control module enters into the normal operation mode, the output is the normal result of comparison.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claim.

What is claimed is:

1. A high-speed data compared latch with auto-adjustment of-offset, comprising: input pair transistors P, input pair transistors N, a compared latch module, an input control module, an output control module and an offset logic control module, wherein the input control module creates two signals to control the input pair transistors P and the input pair transistors N respectively; an output of the input pair transistors P and an output of the input pair transistors N connect to the compared latch module respectively; the latched output of the compared latch module simultaneously connects to the output control module and the offset logic control module; the output control module outputs to a sampling device, the offset logic control module creates two control signals that regulate the number of the input pair transistors P and the input pair transistors N respectively according to reset signal RESET and the latched output of the compared latch module, and achieve self correcting of offset through regulating the number of the input pair transistors P and the input pair transistors N.

2. The high-speed data compared latch with auto-adjustment of-offset, as recited in claim 1, wherein the input pair transistors P comprise N+1 input MOS transistors and N+1 switching transistors that are respectively connected in series and then connected in parallel; the input pair transistors N comprise M+1 input MOS transistors and M+1 switching transistors that are respectively connected in series and then connected in parallel; wherein N and M are greater than or equal to zero.

3. The high-speed data compared latch with auto-adjustment of offset, as recited in claim 1, wherein the compared latch module is capable of comparing the signals that are output by the input pair transistors P and the input pair transistors N for getting corresponding latched output under the control of an input clock.

4. The high-speed data compared latch with auto-adjustment of offset, as recited in claim 2, wherein the compared latch module is capable of comparing the signals that are output by the input pair transistors P and the input pair transistors N for getting corresponding latched output under the control of an input clock.

5. The high-speed data compared latch with auto-adjustment of offset, as recited in claim 1, wherein the offset logic control module creates IN_EN signal as enable control signal of the input control module through the co-acting of the reset signal RESET and the latched output signal of the compared latch module.

6. The high-speed data compared latch with auto-adjustment of offset, as recited in claim 2, wherein the offset logic control module creates IN_EN signal as enable control signal of the input control module through the co-acting of the reset signal RESET and the latched output signal of the compared latch module.

7. The high-speed data compared latch with auto-adjustment of offset, as recited in claim 4, wherein the offset logic control module creates IN_EN signal as enable control signal of the input control module through the co-acting of the reset signal RESET and the latched output signal of the compared latch module.

8. The high-speed data compared latch with auto-adjustment of offset, as recited in claim 1, wherein the offset logic control module creates OUT_EN signal as enable control signal of the output control module through the co-acting of the reset signal RESET and the latched output signal of the compared latch module.

9. The high-speed data compared latch with auto-adjustment of offset, as recited in claim 2, wherein the offset logic control module creates OUT_EN signal as enable control signal of the output control module through the co-acting of the reset signal RESET and the latched output signal of the compared latch module.

10. The high-speed data compared latch with auto-adjustment of offset, as recited in claim 7, wherein the offset logic control module creates OUT_EN signal as enable control signal of the output control module through the co-acting of the reset signal RESET and the latched output signal of the compared latch module.

11. The high-speed data compared latch with auto-adjustment of offset, as recited in claim 1, wherein the offset logic control module creates two signals CON_P[0:N], CON_N[0:M] as control signals that adjust the number of the input pair transistors P and the input pair transistors N through the co-acting of the reset signal RESET and the latched output signal of the compared latch module.

12. The high-speed data compared latch with auto-adjustment of offset, as recited in claim 2, wherein the offset logic control module creates two signals CON_P[0:N], CON_N[0:M] as control signals that adjust the number of the input pair transistors P and the input pair transistors N through the co-acting of the reset signal RESET and the latched output signal of the compared latch module.

13. The high-speed data compared latch with auto-adjustment of offset, as recited in claim 10, wherein the offset logic control module creates two signals CON_P[0:N], CON_N[0:M] as control signals that adjust the number of the input pair transistors P and the input pair transistors N through the co-acting of the reset signal RESET and the latched output signal of the compared latch module.

14. The high-speed data compared latch with auto-adjustment of offset, as recited in claim 1, wherein the work process is as follows:
when RESET is in effect, the offset logic control module is in reset:
IN_EN=0, the input control module creates two signals INN_P, INN_N under the control of the signal IN_EN, the two signals INN_P, INN_N are both common mode of input data of the high-speed data compared latch with auto-adjustment of offset;
OUT_EN=0: the output control module is in reset, the output of the high-speed data compared latch is always zero;
CON_P[0:N]/CON_N[0:M] are the control signals of N+1/M+1 that control the number of the two input pair transistors respectively, in this state, CON_P[0: N]=11, CON_N[0:M]=I2 are the default, wherein I1/I2 meet: 0<I1<N+1,0<I2<M+1;
when RESET is not in effect, the output of the offset logic control module is IN_EN=0/OUT_EN=0, the input of the input pair transistors P and the input pair transistors N is INN_P=INN_N, the high-speed data compared latch with auto-adjustment of offset is in the state of auto-adjustment of offset, the output remains zero, the compared latch module compares the output of the input pair transistors P and the input pair transistors N when the rise time of an input clock comes, the result of comparison is unchanging under the input clock's high status and not influenced by the input state of the input pair transistors P and the input pair transistors N, when the input clock turns in low status, the result of comparison is sent to the offset logic control module and the output control module simultaneously as the latched output of the compared latch module, the offset logic control module accumulates compared latch output data in x input clock cycles, carries out the auto-adjustment of offset through the judgement of an accumulated value.

15. The high-speed data compared latch with auto-adjustment of offset, as recited in claim 2, wherein the work process is as follows:
when RESET is in effect, the offset logic control module is in reset:
IN_EN=0, the input control module creates two signals INN_P, INN_N under the control of the signal IN_EN, the two signals INN_P, INN_N are both common mode of input data of the high-speed data compared latch with auto-adjustment of offset;
OUT_EN=0: the output control module is in reset, the output of the high-speed data compared latch is always zero;
CON_P[0:N]/CON_N[0:M] are the control signals of N+1/M+1 that control the number of the two input pair transistors respectively, in this state, CON_P[0: N]=11, CON_N[0:M]=I2 are the default, wherein I1/I2 meet: 0<I1<N+1,0<I2<M+1;
when RESET is not in effect, the output of the offset logic control module is IN_EN=0/OUT_EN=0, the input of the input pair transistors P and the input pair transistors N is INN_P=INN_N, the high-speed data compared latch with auto-adjustment of offset is in the state of auto-adjustment of offset, the output remains zero. the compared latch module compares the output of the input pair transistors P and the input pair transistors N when the rise time of an input clock comes, the result of comparison is unchanging under the input clock's high status and not influenced by the input state of the input pair transistors P and the input pair transistors N, when the input clock turns in low status, the result of comparison is sent to the offset logic control module and the output control module simultaneously as the latched output of the compared latch module, the offset logic control module accumulates compared latch output data in x input clock cycles, carries out the auto-adjustment of offset through the judgement of an accumulated value.

16. The high-speed data compared latch with auto-adjustment of offset, as recited in claim 13, wherein the work process is as follows:
when RESET is in effect, the offset logic control module is in reset:
IN_EN=0, the input control module creates two signals INN_P, INN_N under the control of the signal IN_EN, the two signals INN_P, INN_N are both common mode of input data of the high-speed data compared latch with auto-adjustment of offset;
OUT_EN=0: the output control module is in reset, the output of the high-speed data compared latch is always zero;
CON_P[0:N]/CON_N[0:M] are the control signals of N+1/M+1 that control the number of the two input pair transistors respectively, in this state, CON_P[0: N]=11, CON_N[0:M]=I2 are the default, wherein I1/I2 meet: 0<I1<N+1,0<I2<M+1;
when RESET is not in effect, the output of the offset logic control module is IN_EN=0/OUT_EN=0, the input of the input pair transistors P and the input pair transistors N is INN_P=INN_N, the high-speed data compared latch with auto-adjustment of offset is in the state of auto-adjustment of offset, the output remains zero. the compared latch module compares the output of the input pair transistors P and the input pair transistors N when the rise time of an input clock comes, the result of comparison is unchanging under the input clock's high status and not influenced by the input state of the input pair transistors P and the input pair transistors N, when the input clock turns in low status, the result of comparison is sent to the offset logic control module and the output control module simultaneously as the latched output of the compared latch module, the offset logic control module accumulates compared latch output data in x input clock cycles, carries out the auto-adjustment of offset through the judgement of an accumulated value.

17. The high-speed data compared latch with auto-adjustment of offset, as recited in claim 1, wherein the work process is as follows:
if an accumulated value of compared latch output data is zero in x input clock cycles, which means that the number of the input pair transistors N is bigger than the input pair transistors P by mismatch, the output control signal CON_P[0:N] of the offset logic control module keep unchanging, CON_N[0:M] reduce one on the original basis, that is, the number of the input pair transistors N reduce one on the original basis on the state that the number of the input pair transistors P keep unchanging; and at the same time an accumulated counting value of the offset logic control module resets to zero;
if the accumulated value of the compared latch output data is X in x input clock cycles, which means the number of the input pair transistors P is bigger than the input pair transistors N by mismatch, the output control signal CON_N[0:M] of the offset logic control module keep unchanging, CON_P[0::N] reduce one on the original basis, that is, the number of the input pair transistors P reduce one on the original basis on the state that the number of the input pair transistors N keep unchanging; and at the same time the accumulated counting value of the offset logic control module resets to zero;
the above process is repeated until the accumulated value of the compared latch output data is bigger than zero and smaller than X in x input clock cycles, which indicates that the auto-correcting to the mismatch of the input pair transistors P and the input pair transistors N is finished;
after finishing the auto-correcting to the mismatch, the output of the offset logic control module IN_EN=1,the input control module enters into normal operation mode, INN_P is the positive input of the input data of the high-speed data compared latch with auto-adjustment of offset, INN_N is the negative input of the input data of the high-speed data compared latch with auto-adjustment of offset; the output of the offset logic control module OUT_EN=1, the output control module enters into the normal operation mode, the output is the normal result of comparison.

18. The high-speed data compared latch with auto-adjustment of offset, as recited in claim 2, wherein the work process is as follows:
if an accumulated value of compared latch output data is zero in x input clock cycles, which means that the number of the input pair transistors N is bigger than the input pair transistors P by mismatch, the output control signal CON_P[0:N] of the offset logic control module keep unchanging, CON_N[0:M] reduce one on the original basis, that is, the number of the input pair transistors N reduce one on the original basis on the state that the number of the input pair transistors P keep unchanging; and at the same time an accumulated counting value of the offset logic control module resets to zero;
if the accumulated value of the compared latch output data is X in x input clock cycles, which means the number of the input pair transistors P is bigger than the input pair transistors N by mismatch, the output control signal CON_N[0:M] of the offset logic control module keep unchanging, CON_P[0::N] reduce one on the original basis, that is, the number of the input pair transistors P reduce one on the original basis on the state that the number of the input pair transistors N keep unchanging; and at the same time the accumulated counting value of the offset logic control module resets to zero;
the above process is repeated until the accumulated value of the compared latch output data is bigger than zero and smaller than X in x input clock cycles, which indicates that the auto-correcting to the mismatch of the input pair transistors P and the input pair transistors N is finished;
after finishing the auto-correcting to the mismatch, the output of the offset logic control module IN_EN=1,the input control module enters into normal operation mode, INN_P is the positive input of the input data of the high-speed data compared latch with auto-adjustment of offset, INN_N is the negative input of the input data of the high-speed data compared latch with auto-adjustment of offset; the output of the offset logic control module OUT_EN=1, the output control module enters into the normal operation mode, the output is the normal result of comparison.

19. The high-speed data compared latch with auto-adjustment of offset, as recited in claim 14, wherein the work process is as follows:
if an accumulated value of compared latch output data is zero in x input clock cycles, which means that the number of the input pair transistors N is bigger than the input pair transistors P by mismatch, the output control signal CON_P[0:N] of the offset logic control module keep unchanging, CON_N[0:M] reduce one on the original basis, that is, the number of the input pair transistors N reduce one on the original basis on the state that the number of the input pair transistors P keep unchanging; and at the same time an accumulated counting value of the offset logic control module resets to zero;
if the accumulated value of the compared latch output data is X in x input clock cycles, which means the number of the input pair transistors P is bigger than the input pair transistors N by mismatch, the output control signal CON_N[0:M] of the offset logic control module keep unchanging, CON_P[0::N] reduce one on the original basis, that is, the number of the input pair transistors P reduce one on the original basis on the state that the number of the input pair transistors N keep unchanging; and at the same time the accumulated counting value of the offset logic control module resets to zero;
the above process is repeated until the accumulated value of the compared latch output data is bigger than zero and smaller than X in x input clock cycles, which indicates that the auto-correcting to the mismatch of the input pair transistors P and the input pair transistors N is finished;
after finishing the auto-correcting to the mismatch, the output of the offset logic control module IN_EN=1,the input control module enters into normal operation mode, INN_P is the positive input of the input data of the high-speed data compared latch with auto-adjustment of offset, INN_N is the negative input of the input data of the high-speed data compared latch with auto-adjustment of offset; the output of the offset logic control module OUT_EN=1, the output control module enters into the normal operation mode, the output is the normal result of comparison.

20. The high-speed data compared latch with auto-adjustment of offset, as recited in claim 16, wherein the work process is as follows:
if an accumulated value of compared latch output data is zero in x input clock cycles, which means that the number of the input pair transistors N is bigger than the input pair transistors P by mismatch, the output control signal CON_P[0:N] of the offset logic control module keep unchanging, CON_N[0:M] reduce one on the original basis, that is, the number of the input pair transistors N reduce one on the original basis on the state that the number of the input pair transistors P keep unchanging; and at the same time an accumulated counting value of the offset logic control module resets to zero;
if the accumulated value of the compared latch output data is X in x input clock cycles, which means the number of the input pair transistors P is bigger than the input pair transistors N by mismatch, the output control signal CON_N[0:M] of the offset logic control module keep unchanging, CON_P[0::N] reduce one on the original basis, that is, the number of the input pair transistors P reduce one on the original basis on the state that the number of the input pair transistors N keep unchanging; and at the same time the accumulated counting value of the offset logic control module resets to zero;
the above process is repeated until the accumulated value of the compared latch output data is bigger than zero and smaller than X in x input clock cycles, which indicates that the auto-correcting to the mismatch of the input pair transistors P and the input pair transistors N is finished;
after finishing the auto-correcting to the mismatch, the output of the offset logic control module IN_EN=1,the input control module enters into normal operation mode, INN_P is the positive input of the input data of the high-speed data compared latch with auto-adjustment of offset, INN_N is the negative input of the input data of the high-speed data compared latch with auto-adjustment of offset; the output of the offset logic control module OUT_EN=1, the output control module enters into the normal operation mode, the output is the normal result of comparison.
